(19) United States
(12) Patent Application Publication
(10) Pub. No.: US 2025/0176291 A1
(43) Pub. Date: May 29, 2025

(54) IMAGE SENSOR INCLUDING NANO-PHOTONIC MICROLENS ARRAY AND ELECTRONIC APPARATUS INCLUDING THE SAME

(71) Applicant: SAMSUNG ELECTRONICS CO.,LTD., Suwon-si (KR)

(72) Inventors: Sangeun MUN, Suwon-si (KR); Sookyoung Roh, Suwon-si (KR); Hyunsung Park, Suwon-si (KR); Sungmo Ahn, Suwon-si (KR); Choonlae Cho, Suwon-si (KR)

(73) Assignee: SAMSUNG ELECTRONICS CO.,LTD., Suwon-si (KR)

(21) Appl. No.: 18/888,733

(22) Filed: Sep. 18, 2024

(30) Foreign Application Priority Data
Nov. 29, 2023 (KR) 10-2023-0169850

(51) Int. Cl. H01L 27/146

(52) U.S. Cl. CPC H10F 39/8063; H10F 39/182

(57) ABSTRACT

Provided is an image sensor including a sensor substrate including a plurality of sensing elements, a color filter layer on the sensor substrate and including a plurality of color filters configured to transmit light of different colors, and a nano-photonic lens array on the color filter layer and including a plurality of nanostructures that are configured to concentrate incident light on the plurality of sensing elements, wherein the nano-photonic lens array includes a plurality of main lenses and a plurality of corner lenses respectively corresponding to the plurality of main lenses, the plurality of corner lenses being smaller than the plurality of main lenses, and wherein a size of each of the plurality of main lenses is three times or more larger than a size of each of the plurality of corner lenses.

### CROSS-REFERENCE TO RELATED APPLICATION

This application is based on and claims priority to Korean Patent Application No. 10-2023-0169850, filed on Nov. 29, 2023, in the Korean Intellectual Property Office, the disclosure of which is incorporated herein in its entirety by reference.

### BACKGROUND

### 1. Field

Example embodiments of the present disclosure relate to an image sensor including a nano-photonic microlens array and an electronic apparatus including the image sensor.

### 2. Description of Related Art

An image sensor may include a plurality of pixels (PX) arranged two-dimensionally. Each PX may include photodiodes (PD). The PDs may convert incident light into an electrical signal.

Recently, the demand for improved image sensors in various fields such as digital cameras, camcorders, smartphones, game devices, security service cameras, medical micro cameras, robots, and vehicles has increased due to the development of computer and telecommunications industry, and interest in high dynamic range (HDR) image sensors of which the dynamic ranges may be expanded more broadly has been increased.

### SUMMARY

One or more example embodiments provide an image sensor including a nano-photonic microlens array and an electronic apparatus including the image sensor.

Additional aspects will be set forth in part in the description which follows and, in part, will be apparent from the description, or may be learned by practice of the example embodiments.

According to an aspect of an example embodiment, there is provided an image sensor including a sensor substrate including a plurality of sensing elements, a color filter layer on the sensor substrate and including a plurality of color filters configured to transmit light of different colors, and a nano-photonic lens array on the color filter layer and including a plurality of nanostructures that are configured to concentrate incident light on the plurality of sensing elements, wherein the nano-photonic lens array includes a plurality of main lenses and a plurality of corner lenses respectively corresponding to the plurality of main lenses, the plurality of corner lenses being smaller than the plurality of main lenses, and wherein a size of each of the plurality of main lenses is three times or more larger than a size of each of the plurality of corner lenses.

Each of the plurality of the main lenses and each of the plurality of the corner lenses corresponding to each other may be adjacent to each other.

The plurality of main lenses may include a first main lens and a second main lens, and the plurality of corner lenses may include a first corner lens corresponding to the first main lens and a second corner lens corresponding to the second main lens.

The first main lens includes a plurality of first main structures, the second main lens includes a plurality of second main structures, the first corner lens includes a plurality of first corner structures, and the second corner lens may include a plurality of second corner structures.

An arrangement of sizes of the plurality of first main structures may be different from an arrangement of sizes of the plurality of second main structures, and the plurality of first main structures and the plurality of second main structures may be configured to form different phase profiles.

A period of the plurality of first main structures may be different from a period of the plurality second main structures.

A period of the plurality of first main structures may be different from a period of the plurality of first corner structures, and a period of the plurality of second main structures may be different from a period of the plurality of second corner structures.

A period of the plurality of first main structures, a period of the plurality of second main structures, a period of the plurality of first corner structures, and a period of the plurality of second corner structures may be identical to one another.

An arrangement of sizes of the plurality of first main structures may be identical to an arrangement of sizes of the plurality of second main structures, and an arrangement of sizes of the plurality of first corner structures may be identical to an arrangement of sizes of the plurality of second corner structures.

A size of each of the plurality of first main structures may decrease and then increase toward a center of the first main lens from a periphery of the first main lens, and a size of each of the plurality of second main structures may decrease and then increase toward a center of the second main lens from a periphery of the second main lens.

Based on incident light having a chief ray angle (CRA) greater than 0 being incident on the first main lens, the plurality of first main structures may be asymmetrical with respect to a center of the first main lens and the plurality of first corner structures may be asymmetrical with respect to a center of the first corner lens.

The plurality of pixels may be periodically arranged in a first direction and a second direction perpendicular to the first direction, and the plurality of nanostructures may be periodically arranged in the first direction and the second direction.

The plurality of pixels may be arranged in a first direction and a second direction perpendicular to the first direction, and the plurality of nanostructures may be periodically arranged in a direction between the first direction and the second direction.

The nano-photonic lens array may include at least one layer including the plurality of nanostructures.

The image sensor may further include an anti-reflection layer on the nano-photonic lens array.

The image sensor may further include a planarization layer between the color filter layer and the nano-photonic lens array.

The image sensor may further include an encapsulation layer between the planarization layer and the nano-photonic lens array.

The image sensor may further include an etch stop layer between the encapsulation layer and the nano-photonic lens array.

According to another aspect of an example embodiment, there is provided an electronic apparatus including an image sensor configured to convert an optical image to an electrical signal, and a processor configured to control an operation of the image sensor and store and output a signal generated from the image sensor, wherein the image sensor includes a sensor substrate including a plurality of pixels, a color filter layer on the sensor substrate and including a plurality of color filters configured to transmit light of different colors, and a nano-photonic lens array on the color filter layer and including a plurality of nanostructures that are configured to concentrate incident light on the plurality of pixels, wherein the nano-photonic lens array includes a plurality of main lenses and a plurality of corner lenses respectively corresponding to the plurality of main lenses, the plurality of corner lenses being smaller than the plurality of main lenses, and wherein a size of each of the plurality of the main lenses is three times or more larger than a size of each of the plurality of the corner lenses.

### BRIEF DESCRIPTION OF DRAWINGS

The above and other aspects, features, and advantages of embodiments of the disclosure will be more apparent from the following description taken in conjunction with the accompanying drawings, in which:

FIG. 1 is a block diagram of an image sensor according to an example embodiment;

FIG. 2 illustrates a pixel arrangement of a pixel array of an image sensor according to an example embodiment;

FIGS. 3A and 3B are cross-sectional views each illustrating a configuration of a pixel array of an image sensor according to an example embodiment;

FIG. 4 is a plan view illustrating a configuration of a sensor substrate of the pixel array of FIGS. 3A and 3B;

FIG. 5 is a plan view illustrating a configuration of a color filter layer of FIGS. 3A and 3B;

FIG. 6 is a plan view illustrating a configuration of a nano-photonic lens array of FIGS. 3A and 3B;

FIG. 7 illustrates a pixel arrangement of a pixel array of an image sensor according to an example embodiment;

FIG. 8 is a plan view illustrating a configuration of a nano-photonic lens array of the pixel array of the image sensor of FIG. 7, according to an example embodiment;

FIG. 9 shows a cross-section of nanostructures of FIG. 8 taken along line C-C′ and an effective lens profile thereof.

FIG. 10 is a plan view illustrating a configuration of a nano-photonic lens array of a pixel array of an image sensor, according to another example embodiment;

FIG. 11 shows a cross-section of nanostructures of FIG. 10 taken along line D-D′ and an effective lens profile thereof;

FIG. 12 is a plan view illustrating a configuration of a nano-photonic lens array of a pixel array of an image sensor, according to another example embodiment;

FIG. 13 shows a cross-section of nanostructures of FIG. 12 taken along line E-E′ and an effective lens profile thereof;

FIG. 14 is a plan view illustrating a nano-photonic lens array of an image sensor according to another example embodiment;

FIG. 15 is a plan view illustrating a nano-photonic lens array of an image sensor according to another example embodiment;

FIG. 16 is a block diagram illustrating an example of an electronic apparatus including an image sensor according to an example embodiment;

FIG. 17 is a block diagram illustrating a camera module of FIG. 16; and

FIGS. 18 and 19 illustrate various example embodiments to which the image sensor is applied.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, embodiments will be described in detail with reference to the accompanying drawings. In the drawings, like reference numerals demote like elements, and sizes of each component are exaggerated for clarity and convenience in explanation. The following embodiments described below are merely illustrative, and various modifications may be possible from the embodiments of the present disclosure.

It will be understood that when an element or layer is referred to as being “on” or “above” another element or layer, the element or layer may be directly on, under, on the left side of, or on the right side of another element or layer or intervening elements or layers may exist between the element or layer and another element or layer. An expression used in the singular encompasses the expression of the plural, unless it has a clearly different meaning in the context. It will be further understood that when a portion is referred to as “comprises” another component, the portion may not exclude another component but may further comprise another component unless the context states otherwise.

The use of the terms of “the above-described” and similar indicative terms may correspond to both the singular forms and the plural forms. Also, the steps of all methods described herein can be performed in any suitable order unless otherwise indicated herein or otherwise clearly contradicted by context. Embodiments are not limited to the described order of the steps.

Also, the terms “ . . . unit”, “ . . . module” used herein specify a unit for processing at least one function or operation, and this may be implemented with hardware or software or a combination of hardware and software.

The connection or connection members of the lines between the elements shown in the drawing are examples of functional connection and/or physical or circuit connections, and may be replaced or be implemented as various functional connections, physical connections, or circuit connections in an actual apparatus.

The use of any and all examples, or exemplary language provided herein, is intended merely to better illuminate embodiments and does not pose a limitation on the scope of embodiments unless otherwise claimed.

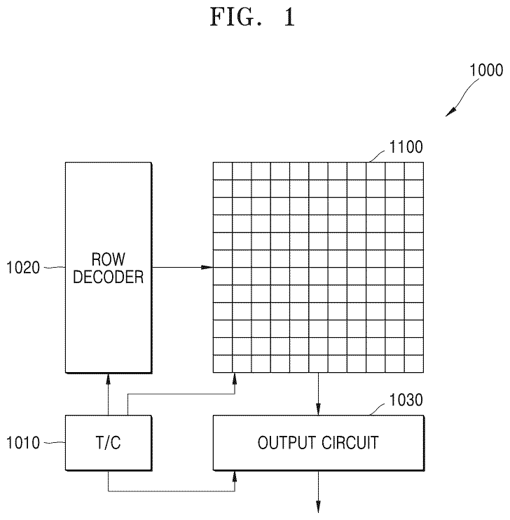

FIG. 1 is a block diagram of an image sensor 1000 according to an example embodiment.

Referring to FIG. 1, the image sensor 1000 may include a pixel array 1100, a timing controller 1010, a row decoder 1020, and an output circuit 1030. The image sensor 1000 may be, for example, a charge coupled device (CDD) image sensor or a complementary metal oxide semiconductor (CMOS) image sensor.

The pixel array 1100 may include pixels arranged two-dimensionally along a plurality of row and columns. The row decoder 1020 may select one of the rows of the pixel array 1100 in response to the row address signal output from the timing controller 1010. The output circuit 1030 may output an optical sensing signal by column unit from a plurality of pixels arranged along the selected row. To this end, the output circuit 1030 may include a column decoder and an analog to digital converter (ADC). For example, the output circuit 1030 may include a plurality of ADCs respectively arranged in the columns between the column decoder and the pixel array 110 or a single ADC arranged on an output terminal of the column decoder. The timing controller 1010, the row decoder 1020, and the output circuit 1030 may be implemented as one chip or respective chips. A processor for processing an image signal output through the output circuit 1030 may be implemented as one chip together with the timing controller 1010, the row decoder 1020, and the output circuit 1030.

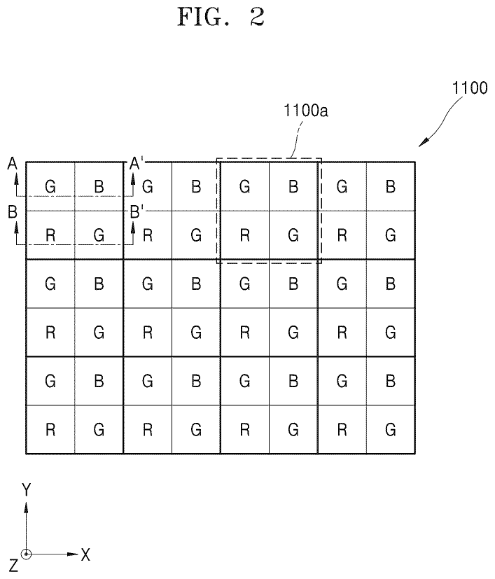

The pixel array 1100 may include a plurality of pixels that detect light of different wavelengths. The arrangement of the pixels may be implemented in various ways. For example, FIG. 2 illustrates a Bayer pattern that may be adopted in a general image sensor.

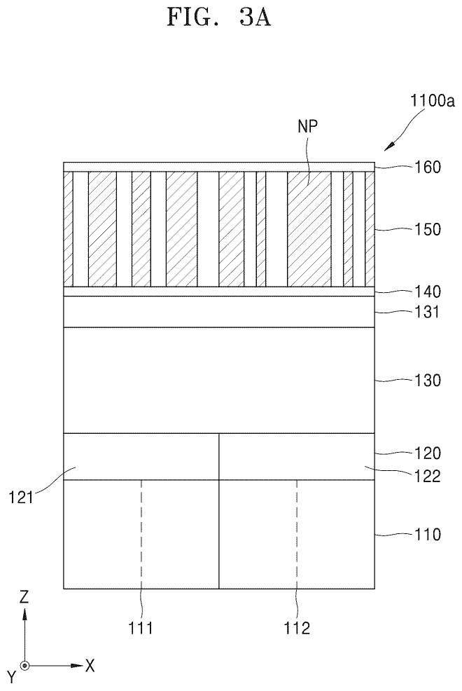

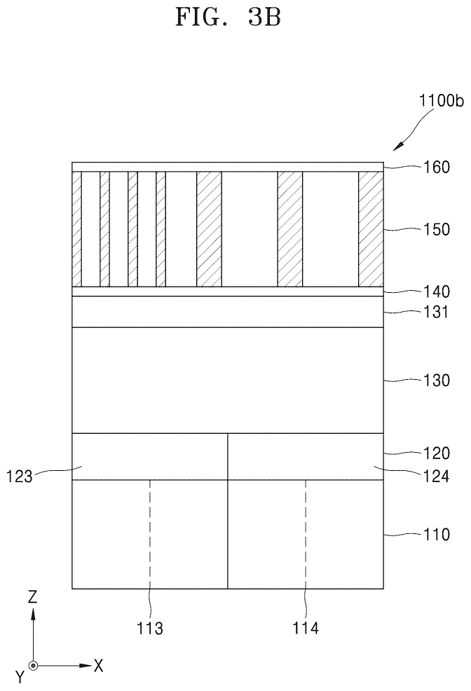

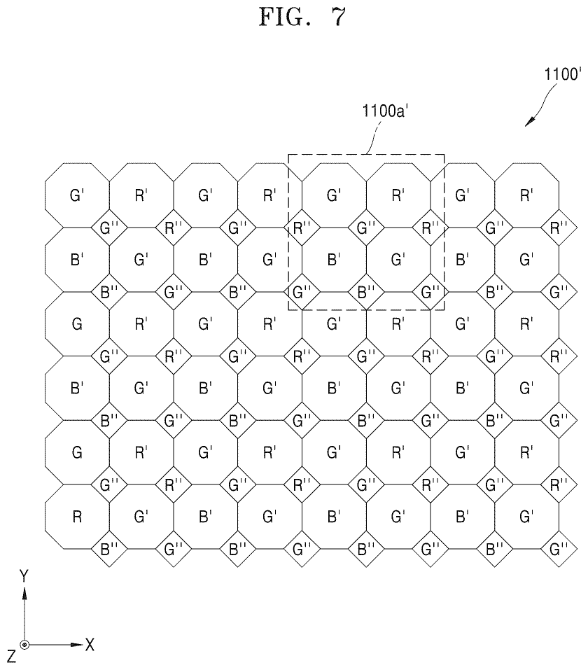

Referring to FIG. 2, one unit pattern 1100a may include four quadrant regions, and first through fourth quadrants may be a blue pixel B, a green pixel G, a red pixel R, and a green pixel G, respectively. The unit pattern may be repeatedly two-dimensionally arranged in a first direction (an X direction) and a second direction (a Y direction). For example, in a unit pattern having a 2×2 array, two green pixels G are placed in one diagonal direction and one blue pixel B and one red pixel R are placed in the other diagonal direction. In the overall pixel arrangement, a first row in which the plurality of green pixels G and the plurality of blue pixels B are alternately arranged in the first direction and a second row in which the plurality of red pixels R and the plurality of green pixels G are alternately arranged may be repetitively arranged in the second direction. According to another example embodiment, a first row in which the plurality of green pixels G and the plurality of red pixels R are alternately arranged in the first direction and a second row in which the plurality of blue pixels B and the plurality of green pixels G are alternately arranged may be repetitively arranged in the second direction. Hereinafter, in FIGS. 3A to 6, for convenience of illustration, the pixel array 1100 is illustrated as having a Bayer pattern structure, but the description below is not limited thereto and may also be applied to a pixel array 1100′ having a pattern structure as illustrated in FIG. 7.

FIGS. 3A and 3B are cross-sectional views each illustrating a configuration of a pixel array of an image sensor according to an example embodiment. FIG. 3A is a cross-sectional view taken along line A-A′ of FIG. 2A, and FIG. 3B is a cross-sectional view taken along line B-B′ of FIG. 2A. FIG. 3A illustrates a cross-section of a green pixels and a blue pixel, and FIG. 3B illustrates a cross-section of a red pixel and a green pixel.

Referring to FIGS. 3A and 3B, the pixel array 1100 may include a sensor substrate 110, a color filter layer 120 arranged on the sensor substrate 110, a transparent planarization layer 130 arranged on the color filter layer 120, a transparent encapsulation layer 131 arranged on the planarization layer 130, and a nano-photonic lens array 150 arranged on the encapsulation layer 131. In addition, the pixel array 1100 may further include an etch stop layer 140 arranged between the encapsulation layer 131 and the nano-photonic lens array 150. In addition, the pixel array 1100 may further include an anti-reflection layer 160 arranged on a light incident surface of the nano-photonic lens array 150. The etch stop layer 140 and the anti-reflection layer 160 may be omitted.

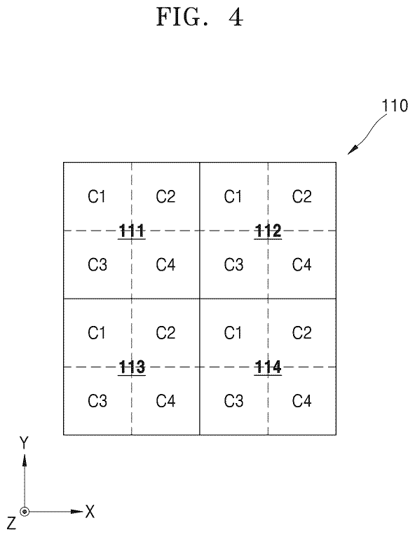

FIG. 4 is a plan view illustrating a configuration of the sensor substrate 110 of the pixel array 1100 illustrated in FIGS. 3A and 3B. Referring to FIG. 4, the sensor substrate 110 may include a plurality of sensing elements to detect incident light. For example, the sensor substrate 110 may include a first sensing element 111, a second sensing element 112, a third sensing element 113, and a fourth sensing 114 each configured to convert incident light into an electrical signal to generate an image signal. The first sensing element 111, the second sensing element 112, the third sensing element 113, and the fourth sensing element 114 may form a unit Bayer pattern. For example, the first sensing element 111 and the fourth sensing element 114 may be green sensing elements that detect green light, the second sensing element 112 may be a blue sensing element that detects blue light, and the third sensing element 113 may be a red sensing element that detects red light.

In the FIGS. 3A, 3B, and 4, only one unit Bayer pattern 1100a including four sensing elements is illustrated, but the pixel array 1100 may include a plurality of Bayer patterns that are two-dimensionally arranged. For example, the plurality of first sensing elements 111 and the plurality of second sensing elements 112 may be alternately arranged along the first direction (the X direction), and, in another cross-section arranged in the second direction (the Y direction) perpendicular to the first direction (the X direction) v), the plurality of third sensing elements 113 and the plurality of fourth sensing elements 114 may be alternately arranged in the first direction (the X direction).

Each of the first to fourth sensing elements 111, 112, 113, and 114 may include a plurality of light detection cells configured to independently detect incident light. For example, the first to fourth sensing elements 111, 112, 113, and 114 may each include a first light detection cell C1, a second light detection cell C2, a third light detection cell C3, and a fourth light detection cell C4. For example, in each of the first to fourth sensing elements 111, 112, 113, and 114, the first to fourth light detection cells C1, C2, C3, and C4 may be arranged in a 2×2 array. FIG. 4 illustrates that the first to fourth sensing elements 111, 112, 113, and 114, each include four light detection cells, but four or more independent light detection cells may be two-dimensionally arranged in a cluster. For example, each of the first to fourth sensing elements 111, 112, 113, and 114 may include a plurality of independent light detection cells arranged in a cluster in a 3×3 array or a 4×4 array.

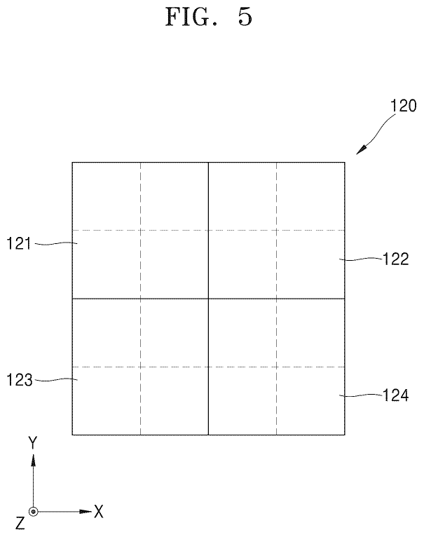

FIG. 5 is a plan view illustrating a configuration of the color filter layer 120 illustrated in FIGS. 3A and 3B.

Referring to FIG. 5, the color filter layer 120 may include a plurality of color filters through which light of a specific wavelength is transmitted and light of other wavelengths are absorbed. For example, the color filter layer 120 may include a first color filter 121 through which light of a first wavelength is transmitted and light of other wavelengths are absorbed, a second color filter 122 through which light of a second wavelength is transmitted and light of other wavelengths are absorbed, a third color filter 123 through which light of a third wavelength penetrates and light of other wavelengths are absorbed, and a fourth color filter 124 through which light of the first wavelength penetrates and light of other wavelengths are absorbed. In FIG. 5, only one unit Bayer pattern is illustrated, but a plurality of first color filters 121 and a plurality of second color filters 122 may be alternately arranged in the first direction (the X direction) and a plurality of third color filters 123 and a plurality of fourth color filters 124 may be alternately arranged in the first direction (the X direction) in another cross-section arranged in the second direction (the Y direction) perpendicular to the first direction (the X direction).

The first color filter 121 may face the first sensing element 111 in the third direction (a Z direction), the second color filter 122 may face the second sensing element 112 in the third direction (the Z direction), the third color filter 123 may face the third sensing element 113 in the third direction (the Z direction), and the fourth color filter 124 may face the fourth sensing element 114 in the third direction (the Z direction). Accordingly, the first sensing element 111 and the fourth sensing element 114 may detect light of the first wavelength transmitted through the corresponding first color filter 121 and fourth color filter 124, respectively. In addition, the second sensing element 112 may detect light of the second wavelength transmitted through the corresponding second color filter 122. In addition, the third sensing element 113 may detect light of the third wavelength transmitted through the corresponding third color filter 123. For example, the first color filter 121 and the fourth color filter 124 may be green color filters transmitting green light, the second color filter 122 may be a blue color filter transmitting blue light, and the third color filter 123 may be a red color filter transmitting red light.

The dotted line shown in FIG. 5 shows boundaries between the light detection cells of the first to fourth sensing elements 111, 112, 113, and 114. As shown in FIG. 5, the first to fourth color filters 121, 122, 123, and 124 may face all the light detection cells in the corresponding first to fourth sensing elements 111, 112, 113, and 114 in the third direction (the Z direction). For example, the first color filter 121 may cover and face all light detection cells in the first sensing element 111, the second color filter 122 may cover and face all light detection cells in the second sensing element 112, the third color filter 123 may cover and face all light detection cells in the third sensing element 113, and the fourth color filter 124 may cover and face all light detection cells in the fourth sensing element 114.

The first to fourth color filters 121, 122, 123, 124 of the color filter layer 120 may include, for example, an organic polymer material. For example, the first to fourth color filters 121, 122, 123, and 124 may include a colorant, a binder resin, and a polymer photoresist. The first and fourth color filters 121 and 124 may be organic color filters including a green organic dye or a green organic pigment as a colorant, the second color filter 122 may be an organic color filter including a blue organic dye or a blue organic pigment as a colorant, and the third color filter 123 may be an organic color filter including a red organic dye or a red organic pigment as a colorant. Although not shown in FIGS. 3A, 3B, and 5 for convenience, the color filter layer 120 may further include a black matrix arranged on the boundaries between the first to fourth color filters 121, 122, 123, and 124. The black matrix may include, for example, carbon black.

In FIGS. 3A and 3B, the color filter layer 120 is shown as having a flat upper surface, but embodiments are not limited thereto, and the upper surface of each of the first to fourth color filters 121, 122, 123, and 124 may not be flat. In addition, thicknesses of the first to fourth color filters 121, 122, 123, and 124 and the black matrix therebetween in the third direction (the Z direction) may not be the same. The planarization layer 130 arranged on the color filter layer 120 may provide a flat surface for forming the nano-photonic lens array 150 on the planarization layer 130. The planarization layer 130 may include an organic polymer material suitable for depositing on the color filter layer 120 formed of organic materials and easier to form a flat surface. The organic polymer material forming the planarization layer 130 may have transparent characteristics with respect to visible light. For example, the planarization layer 130 may include at least one organic polymer material of epoxy resin, polyimide, polycarbonate, polyacrylate, and polymethyl methacrylate (PMMA). The planarization layer 130 may be formed on the color filter layer 120 through, for example, a spin coating method, and may have a flat upper surface through heat treatment.

The encapsulation layer 131 may be further arranged on the planarization layer 130. The encapsulation layer 131 may act as a protective layer to prevent damage to the planarization layer 130 formed of an organic polymer material in the process of forming the nano-photonic lens array 150 on the planarization layer 130. In addition, the encapsulation layer 131 may act as a diffusion prevention layer to prevent a metal component of the color filter layer 120 from passing through the planarization layer 130 to be exposed to the outside due to a high temperature in the process of forming the nano-photonic lens array 150. To this end, the bag layer 131 may include an inorganic material. The inorganic material of the encapsulation layer 131 may be formed at a temperature lower than a process temperature for forming the nano-photonic lens array 150 and may include a transparent material with respect to visible light. In addition, a refractive index of the encapsulation layer 131 needs to be similar to a refractive index of the planarization layer 130 so as to reduce reflection loss at an interface between the planarization layer 130 and the encapsulation layer 131. For example, the encapsulation layer 131 may include at least one inorganic material from silicon oxide (SiO₂), silicon nitride (SiN), and silicon oxynitride (SiON).

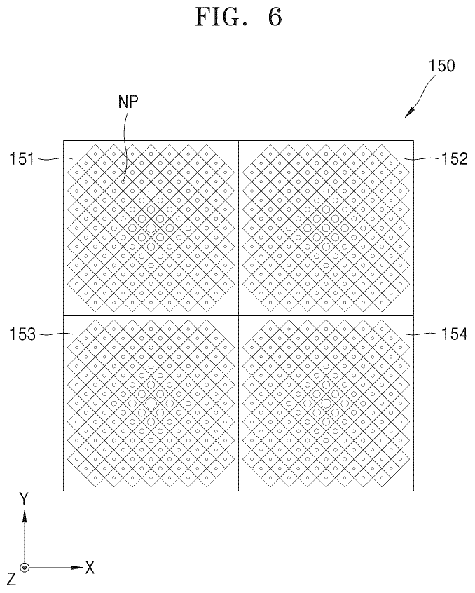

FIG. 6 is a plan view illustrating a configuration of the nano-photonic lens array 150 shown in FIGS. 3A and 3B.

Referring to FIG. 6, the nano-photonic lens array 150 may include the first lens 151 corresponding to the first sensing element 111, a second lens 152 corresponding to the second sensing element 112, a third lens 153 corresponding to the third sensing element 113, and a fourth lens 154 corresponding to the fourth sensing element 114. For example, the first lens 151 may face the first sensing element 111 in the third direction (the Z direction), the second lens 152 may face the second sensing element 112 in the third direction (the Z direction), the third lens 153 may face the third sensing element 113 in the third direction (the Z direction, and the fourth lens 154 may face the fourth sensing element 114 in the third direction (the Z direction). In FIG. 6, only one unit Bayer pattern is illustrated, but a plurality of first lenses 151 and a plurality of second lenses 152 may be alternately arranged in the first direction (the X direction) and a plurality of third lenses 153 and a plurality of fourth lenses 154 may be alternately arranged in the first direction (the X direction) in another cross-section arranged in the second direction (the Y direction) perpendicular to the first direction (the X direction).

The first to fourth lenses 151, 152, 153, and 154 each may be configured to condense light onto the corresponding sensing element among the first to fourth sensing elements 111, 112, 113, and 114. For example, the first lens 151 may condense incident light onto the first sensing element 111 and the second lens 152 may condense incident light onto the second sensing element 112. In addition, the third lens 153 may condense incident light onto the third sensing element 113 and the fourth lens 154 may condense incident light onto the fourth sensing element 114. For example, the nano-photonic lens array 150 may condense light of the first wavelength onto the first sensing element 111 and the fourth sensing element 114, light of the second wavelength onto the second sensing element 112, and light of the third wavelength onto the third sensing element 113.

To this end, the first to fourth lenses 151, 152, 153, and 154 may each include a plurality of nanostructures NP to condense light. The shape, size (the width and height), distance, arrangement form, etc. of the plurality of nanostructures NP may be determined such that the first to fourth lenses 151, 152, 153, and 154 have a predetermined effective lens profile. FIG. 6 illustrates that the diameters of the nanostructures NP are the same, but embodiments are not limited thereto, and the diameters of the nanostructures NP may vary. In addition, the arrangement form of the nanostructures NP may also be variously modified.

The size of the nanostructure NP may be less than the wavelength of visible light. The size of the nanostructure NP may be, for example, less than a blue wavelength. For example, the cross-sectional width (or diameter) of the nanostructure NP may be less than 400 nm, 300 nm, or 200 nm. The height of the nanostructure NP may be about 500 nm to about 1500 nm, and the height may be greater than the width of the cross-section.

The nanostructure NP may have a relatively high refractive index compared to the surrounding materials and may include a material with a relatively low absorption rate in the visible light band. For example, the nanostructure NP may include c-Si, p-Si, a-Si, a Group III-V compound semiconductor (e.g., gallium phosphide (GaP), gallium nitride (GaN), gallium arsenide (GaAs), etc.), silicon carbide (SiC), titanium oxide (TiO₂), silicon nitride (SiN₃), zinc sulfide (ZnS), zinc selenide (ZnSe), silicon nitride (Si₃N₄), and/or a combination thereof. The periphery of the nanostructure NP may include dielectric materials with a relatively low refractive index and a relatively low absorption rate in the visible light band. For example, the periphery of the nanostructure NP may be filled with siloxane-based spin on glass (SOG), SiO₂, Si₃N₄, aluminum oxide (Al₂O₃), air, etc.

The refractive index of the nanostructure NP may be greater than or equal to about 2.0 in light having a wavelength of about 630 nm, and the refractive index of the surrounding materials may be greater than or equal to about 1.0 and less than 2.0 in light having a wavelength of about 630 nm. In addition, a difference between the refractive index of the nanostructure NP and the refractive index of the surrounding materials may be greater than or equal to about 0.5. A refractive index of nanostructure NP being different from a refractive index of the surrounding materials may change the phase of light transmitting through the nanostructure NP.

A phase distribution of light transmitted through the nano-photonic lens array 150 may be greatest at the center of each of the first to fourth lenses 151, 152, 153, and 154 and decrease away from the center of each of the first to fourth lenses 151, 152, 153, and 154. For example, a position of the light immediately after passing through the nano-photonic lens array 150, that is, in the form of a concentric circle, the phase of light in a lower surface of the nano-photonic lens array 150 or an upper surface of the planarization layer 130 may be greatest in the center of each of the first to fourth lenses 151, 152, 153, and 154 and be gradually decrease away from the center of each of the first to fourth lenses 151, 152, 153, and 154.

A phase delay amount of light transmitted through the center of each of the lenses 151, 152, 153, and 154 is not the greatest. The above description may refer to a wrapped phase distribution of, for example, when the phase of light transmitted through the first lens 151 is 2π and the phase delay of light transmitted through another position has a value greater than 2π, a value from which 2nπ is removed. For example, when the phase of light transmitted through the center of the first lens 151 is 2π and the phase of light transmitted through the periphery of the first lens 151 is 3π, the phase in the periphery of the first lens 151 may be the remaining π after removing 2π from 3π (n=1).

A high dynamic range (HDR) image sensor in which small corner pixels are located between large main pixels may be applied to, for example, some image sensors for automotive. The HDR image sensor may use light received from the main pixels in at a low illuminance, and use light received from the corner pixels at a high illuminance, thereby expanding the dynamic range.

FIG. 7 illustrates a pixel arrangement of the pixel array 1100′ of an image sensor according to an example embodiment. The pixel array 1100′ shown in FIG. 7 may be applied to, for example, an HDR image sensor. In FIG. 7, only some pixels included in the pixel array 1100′ are illustrated for convenience, and the same applies below.

Referring to FIG. 7, one unit pattern 1100a′ may include four main pixels (a green pixel G′, a red pixel R′, a blue pixels B′, and a green pixel G′) (hereinafter, also referred to as the green main pixel G′, the red main pixel R′, and the blue main pixel B′) and four corner pixels (a green pixel G″, a red pixel R″, a blue pixel B″, and a green pixel G″) (hereinafter, also referred to as the green corner pixel G″, the red corner pixel R″, and the blue corner pixel B″). The corner pixels G″, R″, B″, and G″ may be arranged at a diagonal side of the main pixels G′, R′, G′, and B′. For example, the green corner pixel G″ may be arranged in a diagonal direction of the green main pixel G″, the red corner pixel R″ may be arranged in a diagonal direction of the red main pixel R′, and the blue corner pixel B″ may be arranged in a diagonal direction of the blue main pixel B′. Sizes of the main pixels G′, R′, B′, and G′ may be greater than sizes of corner pixels G″, R″, B″, and G″.

In FIG. 7, the main pixels G′, R′, B′, and G′ are illustrated as being octagonal, and the corner pixels G″, R″, B″, and G″ are illustrated as being rectangular, but are not limited thereto and may be provided in various forms. The main pixels G′, R′, B′, and G′ and the corner pixels G″, R″, B″, and G″ have similar cross-sectional structures with those shown in FIGS. 3A and 3B, and detailed descriptions thereof are omitted.

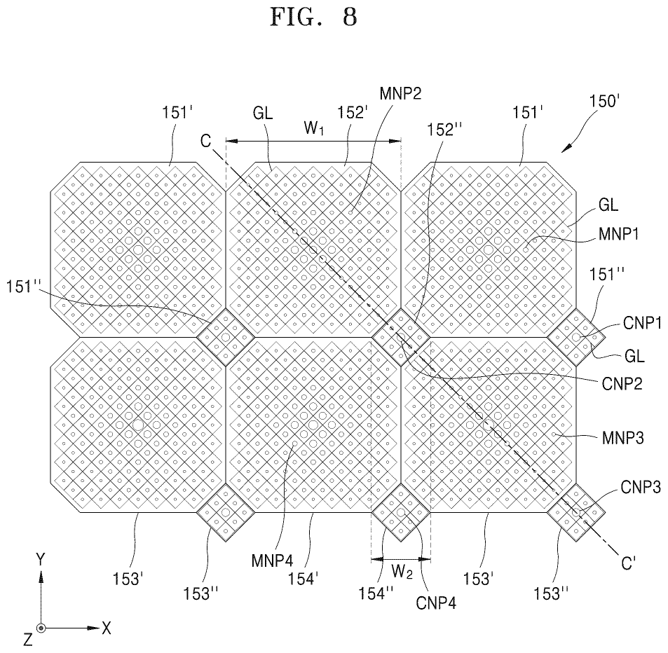

FIG. 8 is a plan view illustrating a configuration of a nano-photonic lens array 150′ of the pixel array 1100′ of the image sensor of FIG. 7, according to an example embodiment.

Referring to both FIGS. 7 and 8, the nano-photonic lens array 150′ according to the example embodiment may include main lenses 151′, 152′, 153′, and 154′ (hereinafter, also referred to as the first main lens 151′, the second main lens 152′, the third main lens 153′, and the fourth main lens 154′) respectively provided in the main pixels G′, R′, B′, and G′ and corner lenses 151″, 152″, 153″, and 154″ (hereinafter, also referred to as the first corner lens 151″, the second corner lens 152″, the third corner lens 153″, and the fourth corner lens 154″) respectively provided in the corner pixels G″, R″, B″, and G″. The main lenses 151′, 152′, 153′, and 154′ may respectively face the main pixels G′, R′, B′, and G′ in the third direction (the Z direction). In addition, the corner lenses 151″, 152″, 153″, and 154″ may respectively face the corner pixels G″, R″, B″, and G″ in the third direction (the Z direction). The first corner lens 151″ may be provided in a diagonal direction of the first main lens 151′, and the second corner lens 152″ may be provided in a diagonal direction of the second main lens 152′. In addition, the third corner lens 153″ may be provided in a diagonal direction of the third main lens 153, and the fourth corner lens 154″ may be provided in a diagonal direction of the fourth main lens 154′.

Each of the main lenses 151′, 152′, 153′, and 154′ may and the corner lenses 151″, 152″, 153″, and 154″ may include a plurality of nanostructures. FIG. 8 shows grid lines GL showing a period of a plurality of nanostructures for convenience, and may also be applied to later drawings.

Hereinafter, the plurality of nanostructures provided in the main lenses 151′, 152′, 153′, and 154′ may be referred to as main nanostructures, and the plurality of nanostructures provided in the corner lenses 151″, 152″, 153″, and 153″ may be referred to as corner structures.

For example, the plurality of nanostructures provided in the first main lens 151′ may be referred to as a first main structure MNP1 and the plurality of nanostructures provided in the second main lens 152′ may be referred to as a second main structure MNP2. In addition, the plurality of nanostructures provided in the third main lens 153′ may be referred to as a third main structure MNP3 and the plurality of nanostructures provided in the fourth main lens 154′ may be referred to as a fourth main structure MNP4.

The plurality of nanostructures provided in the first corner lens 151″ may be referred to as a first corner structure CNP1 and the plurality of nanostructures provided in the second corner lens 152″ may be referred to as a second corner structure CNP2. In addition, the plurality of nanostructures provided in the third corner lens 153″ may be referred to as a third corner structure CNP3 and the plurality of nanostructures provided in the fourth corner lens 154″ may be referred to as a fourth corner structure CNP4.

The structural characteristics (e.g., the size, the period, the arrangement form) of the plurality of first main structures MNP1, the second main structures MNP2, the third main structure MNP3, and the fourth main structure MNP4 may be the same, and the structural characteristics of the plurality of first corner structures CNP1, the second corner structures CNP2, the third corner structures CNP3, and the fourth corner structures CNP4 may be the same. According to another example embodiment, the structural characteristics of the first main structure MNP1, the second main structure MNP2, the third main structure MNP3, the fourth main structure MNP4, the first corner structure CNP1, the second corner structure CNP2, the third corner structure CNP3, and the fourth corner structure CNP4may be different from each other.

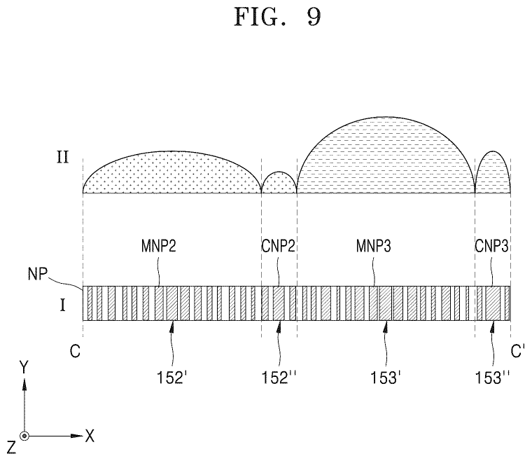

FIG. 9 shows a cross-section of the nanostructures of FIG. 8 taken along line C-C′ and an effective lens profile thereof. An effective lens profile refers to an illustration of a phase profile implemented through nanostructures. In FIG. 9, (I) illustrates the cross-section of the nanostructures of FIG. 8 taken along line C-C′, and Il illustrates an effective lens profile calculated from the cross-section of the nanostructures illustrated in (I) of FIG. 9. The same is applied to the following drawings.

Hereinafter, for convenience, only descriptions regarding the second main lens 152′ and the second corner lens 152″, and the third main lens 153′ and the third corner lens 153″ were provided, but the same may be applied to the first main lens 151′ and the first corner lens 151″, and the fourth main lens 154′ and the fourth corner lens 154″.

Referring to FIG. 9, the second main lens 152′ may include the plurality of second main structures MNP2 and the third main lens 153′ may include the plurality of third main structures MNP3. In addition, the second corner lens 152″ may include the plurality of second corner structures CNP2 and the third corner lens 153″ may include the plurality of third corner structures CNP3.

The plurality of second main structures MNP2 may be formed such that the effective lens profile of the second main lens 152′ is greatest in the center of the second main lens 152′ and decreases away from the center of the second main lens 152′. The plurality of second corner structures CNP2 may be formed such that the effective lens profile of the second corner lens 152″ is greatest in the center of the second corner lens 152″ and decreases away from the center of the second corner lens 152″. In addition, the plurality of third main structures MNP3 may be formed such that the effective lens profile of the third main lens 153′ is greatest in the center of the third main lens 153″ and decreases away from the center of the third main lens 153″. The plurality of third corner structures CNP3 may be formed such that the effective lens profile of the third corner lens 153″ is greatest in the center of the third corner lens 153″ and decreases away from the center of the third corner lens 153″.

The plurality of second main structures MNP2 and the plurality of third main structures MNP3 may have different structural characteristics (e.g., shapes of the nanostructure, sizes (e.g., a width and a height), periods (a distance between adjacent nanostructures), arrangements, shapes, etc.) such that the effective lens profile of the second main lens 152′ and the effective lens profile of the third main lens 153′ are different from each other.

The second main structures MNP2 and the second corner structures CNP2 may include nanostructures with different numbers, sizes (width or height), and/or arrangements such that the second main lens 152′ and the second corner lens 152″ have different lens sizes. In addition, the third main structures MNP3 and the third corner structures CNP3 may include nanostructures with different numbers, sizes (width or height), and/or arrangements such that the third main lens 153′ and the third corner lens 153″ have different lens sizes.

The size of the second main lens 152′ may be the same as that of the third main lens 153′, and the size of the second corner lens 152″ may be the same as that of the third corner lens 153″. The size of the second main lens 152′ may be greater than that of the second corner lens 152″, and the size of the third main lens 153′ may be greater than that of the third corner lens 153″. For example, a width W₁ of the second main lens 152′ may be approximately three times a width W₂ of the second corner lens 152″. If the width W₁ of the second main lens 152′ is about three times the width W₂ of the second corner lens 152″, a plurality of second corner structures CNP2 in the number of NsN may be arranged in the second corner lens 152″, and a plurality of second main structures MNP2 in the number of 3Ns3N may be arranged in the second main lens 152′. Here, as shown in FIG. 8, the period of the plurality of second main structures MNP2 and the period of the plurality of second corner structures CNP2 may be the same.

The effective lens profile of the second main structures MNP2 provided in the second main lens 152′ may be wrapped every point where the phase value becomes a multiple of 2π. Accordingly, the second main structures MNP2 provided in the second main lens 152′ may have sizes (widths) that are increased toward the center of the second main lens 152′ from the periphery of the second main lens 152′, and at a point where the phase value of the effective lens profile becomes a multiple of 2π, inversion of the sizes (widths) of the second main structures MNP2 may occur. For example, the second main structure MNP2 provided in the second main lens 152′ may have a section in which the size (width) thereof decreases toward the center of the second main lens 152′ from the periphery of the second main lens 152′. The same may also be applied to the third main lens 153′.

As the second corner lens 152″ is relatively smaller than the second main lens 152′, the effective lens profile of the nanostructure may not be wrapped, and thus, a section in which an inversion of the width of the nanostructure occurs may not exist in the second corner lens 152″. For example, the plurality of nanostructures provided in the second corner lens 152″ may not have a section in which the width thereof decreases toward the center of the second corner lens 152″ from the periphery of the second corner lens 152″. The same may also be applied to the third corner lens 153″.

The second main structures MNP2 provided in the second main lens 152′ and the third main structures MNP3 provided in the third main lens 153′ may have different sizes and/or arrangements such that the effective lens profile is different in every wavelength band of light detected by each sensing element of the sensor substrate. For example, as shown in FIG. 9, the second and third main structures MNP2 and MNP3 may be configured such that a peak of the effective lens profile of the third main lens 153′ provided in the blue main pixel B′ is greater than a peak of the effective lens profile of the second main lens 152′ provided in the red main pixel R′. When implementing a phase profile such as a lens by using a nanostructure, since a blue focal length is greater than a red focal length, a peak value of the effective lens profile of the third main lens 153′ may be configured to be greater than a peak value of the effective lens profile of the second main lens 152′, such that the focal lengths of the wavelengths may become similar. FIGS. 8 and 9 illustrate a case in which second main structures MNP2 and the third main structures MNP3 have the same period but have different arrangements of sizes. For example, an arrangement of different sizes of the second main structures MNP2 is different from an arrangement of different sizes of the third main structures MNP3.

FIG. 8 illustrates a case in which the first to fourth main structures MNP1, MNP2, MNP3, and MNP4 and the first to fourth corner structures CNP1, CNP2, CNP3, and CNP4 have circular cross-sections, but are not limited thereto and may have various types of cross-sections such as a quadrangle shape or a polygon shape. The main lenses 151′, 152′, 153′, and 154′ may each have a stacked structure of one or two or more layers and may respectively include the first to fourth main structures MNP1, MNP2, MNP3, and MNP4. In addition, the corner lenses 151″, 152″, 153″, and 154″ may each have a stacked structure of one or two or more layers and may respectively include the first to fourth corner structures CNP1, CNP2, CNP3, and CNP4.

When a large main refractive lens and a small corner refractive lens are to be formed in the HDR image sensor, it may be difficult to control the curvature and shape of each of the main lens and the corner lens. In the image sensor (e.g., the HDR image sensor) according to the example embodiment, the large main lens and the small corner lens may be manufactured with the nanostructures by using a semiconductor process to easily implement various sizes of main lenses and corner lenses.

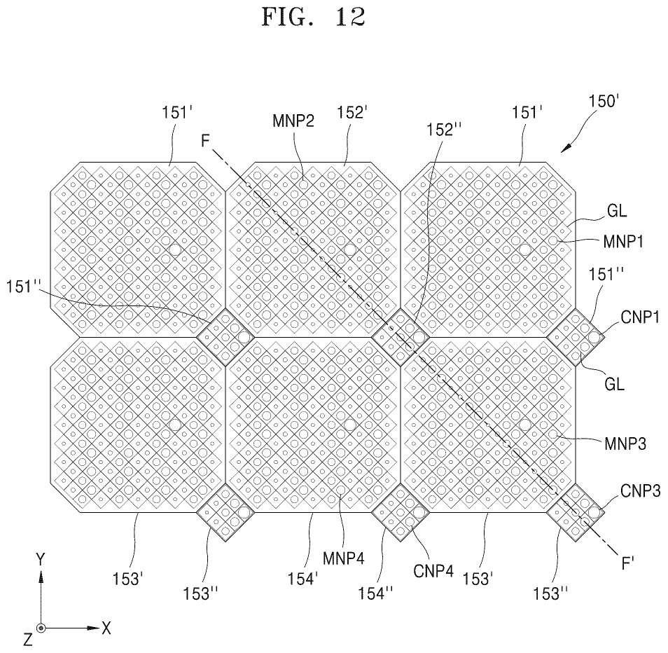

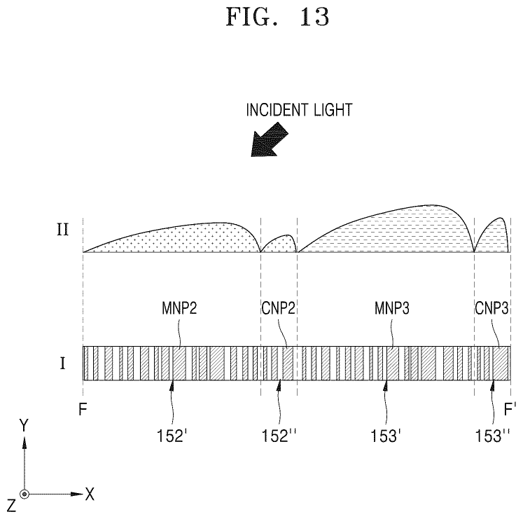

FIG. 12 is a plan view illustrating a configuration of a nano-photonic lens array of an image sensor according to another embodiment, and FIG. 13 illustrates a cross-section of the nanostructures taken along line F-F′ and an effective lens profile thereof. Differences between FIG. 10 and FIGS. 8 and 9 are mainly described.

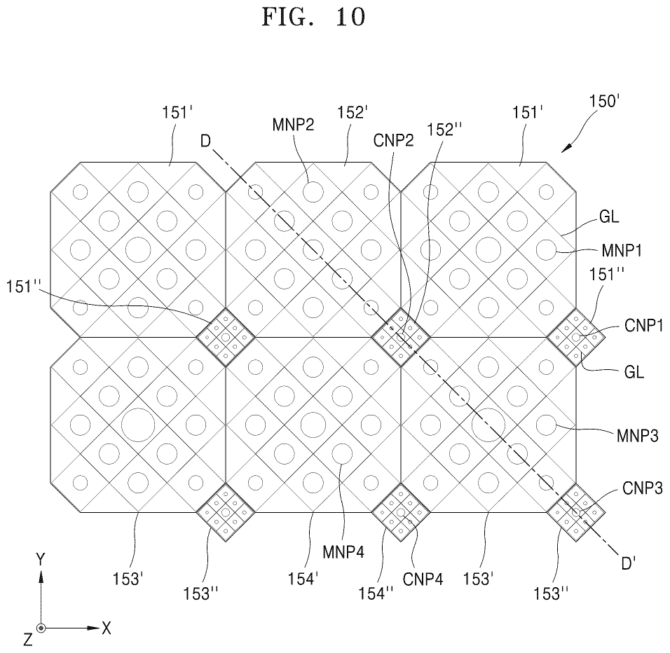

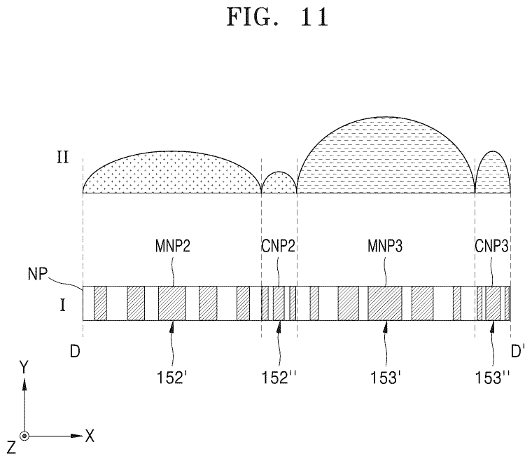

Referring to FIGS. 10 and 11, the periods of the second and third main structures MNP2 and MNP3 respectively provided in the second and third main lenses 152′ and 153′ may be different from the periods of the second and third corner structures CNP2 and CNP3 respectively provided in the second and third corner lenses 152″ and 153″. For example, the period of each of the second and third main structures MNP2 and MNP3) may be greater than the period of each of the second and third corner structures CNP2 and CNP3. In this case, as shown in FIG. 11, a distance between centers of the second main structures MNP2 adjacent to each other in the second main lens 152′ may be greater than a distance between centers of the second corner structures CNP2 adjacent in the second corner lens 152″.

A chief ray angle (CRA) of light incident onto the center of the pixel array 1100 is 0 degrees, but the CRA of incident light may increase toward the edge of the pixel array 1100. The CRA of incident light incident onto the pixels may change according to the location of pixels in the pixel array 1100. When the CRA of incident light incident on the pixels is increased, the sensitivity of the pixels may be reduced. Accordingly, a plurality of nanostructures NP of the nano-photonic lens array 150′ may be asymmetrical to compensate for stray light.

FIG. 12 is a plan view illustrating a nano-photonic lens array of an image sensor according to another example embodiment, and FIG. 13 illustrates a cross-section of the nanostructures taken along line F-F′ and an effective lens profile thereof.

Referring to FIGS. 12 and 13, when incident light is obliquely provided such that CRA>0, the plurality of nanostructures provided in each of the main lenses 151′, 152′, 153′, and 154′ and the corner lenses 151″, 152″, 153″, and 154″ of the nano-photonic lens array 150′ may have an asymmetrical effective lens profile. For example, if incident light is incident in the first direction (the X direction) as shown in FIG. 13, the plurality of nanostructures NP may be provided such that the profile (II) of the second main lens 152′, the second corner lens 152″, the third main lens 153′, and the third corner lens 153″ have an asymmetric arrangement in the first direction (the X direction). In this case, in the cross-section (II) of the nanostructure NP (or the second main structure MNP2, the second corner structure CNP2, the third main structure MNP3, and the third corner structure CNP3) provided in the second main lens 152′, the second corner lens 152″, the third main lens 153′, and the third corner lens 153″, the size or arrangement of the nanostructure NP may be asymmetric with respect to the center of each lens.

In the above, although the periodic direction of the plurality of nanostructures NP provided in each of the main lenses 151′, 152′, 153′, and 154′, and the corner lenses 151″, 152″, 153″, and 154″ of the nano-photonic lens array 150′ is diagonal, the periodic direction of the plurality of nanostructures NP may be applied in various ways.

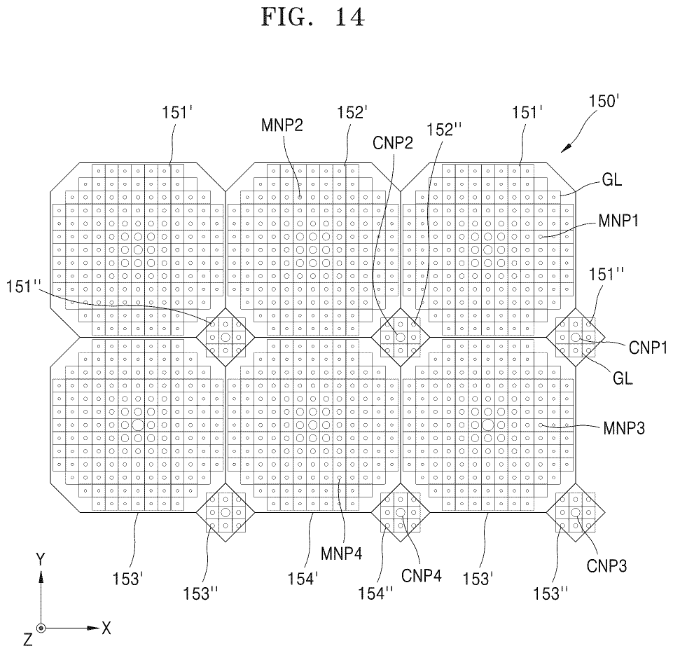

FIG. 14 is a plan view illustrating a nano-photonic lens array of an image sensor according to another example embodiment.

Referring to FIG. 14, the first to fourth main structures MNP1, MNP2, MNP3, and MNP4 respectively forming the main lenses 151′, 152′, 153′, and 154′ may be arranged periodically in the first direction (the X direction) and the second direction (the Y direction). In addition, the first to fourth corner structures CNP1, CNP2, CNP3, and CNP4 respectively forming the corner lenses 151″, 152″, 153″, and 154″ may be arranged periodically in the first direction (the X direction) and the second direction (the Y direction). For example, the first to fourth main structures MNP1, MNP2, MNP3, and MNP4 and the first to fourth corner structures CNP1, CNP2, CNP3, and CNP4 may be arranged periodically in the first direction (the X direction) and the second direction (the Y direction).

FIG. 14 illustrates that the first to fourth main structures MNP1, MNP2, MNP3, and MNP4 have the same period, the first to fourth corner structures CNP1, CNP2, CNP3, and CNP4 have the same period, and the first to fourth main structures MNP1, MNP2, MNP3, and MNP4 and the first to fourth corner structures CNP1, CNP2, CNP3, and CNP4 have the same period. For example, a case in which the first to fourth main structures MNP1, MNP2, MNP3, and MNP4 and the first to fourth corner structures CNP1, CNP2, CNP3, and CNP4 all have the same period is illustrated. However, embodiments are not limited thereto.

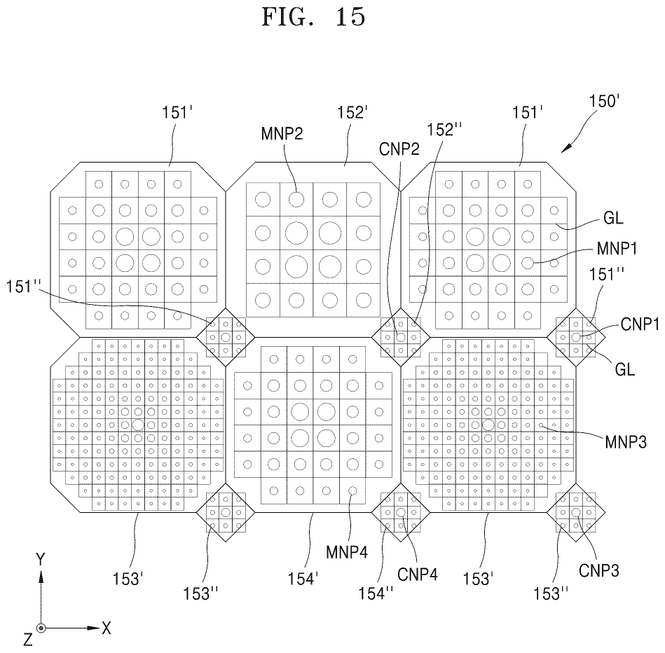

FIG. 15 is a plan view illustrating a nano-photonic lens array of an image sensor according to another example embodiment.

Referring to FIG. 15, the first to fourth main structures MNP1, MNP2, MNP3, and MNP4 respectively forming the main lenses 151′, 152′, 153′, and 154′ may be arranged periodically in the first direction (the X direction) and the second direction (the Y direction). In addition, the first to fourth corner structures CNP1, CNP2, CNP3, and CNP4 respectively forming the corner lenses 151″, 152″, 153″, and 154″ may be arranged periodically in the first direction (the X direction) and the second direction (the Y direction). For example, the first to fourth main structures MNP1, MNP2, MNP3, and MNP4 and the first to fourth corner structures CNP1, CNP2, CNP3, and CNP4 may be arranged periodically in the first direction (the X direction) and the second direction (the Y direction).

The first to fourth main structures MNP1, MNP2, MNP3, and MNP4 may be arranged to have different periods from each other. For example, as shown in FIG. 15, the period of the first main structures MNP1 (or the fourth main structures MNP4) of the first main lens 151′ (or the fourth main lens 154′) corresponding to the green main pixel G′ may be different from the period of the second main structures MNP2 of the second main lens 152′ corresponding to the red main pixel R′. In addition, the period of the first main structures MNP1 (or the fourth main structures MNP4) of the first main lens 151′ (or the fourth main lens 154′) provided correspondingly to the green main pixel G″ may be different from the period of the third main structures MNP3 of the third main lens 153′ provided correspondingly to the blue main pixel B′.

Periods of main structures of pixels that detect light of short wavelengths may be configured to be shorter than periods of main structures of pixels that detect the light of long wavelengths. For example, as shown in FIG. 15, the period of the first main structures MNP1 forming the first main lens 151′ provided in the green main pixel G′ may be shorter than the period of the second main structures MNP2 forming the second main lens 152′ provided in the red main pixel R′. In addition, the period of the third main structures MNP3 forming the third main lens 153′ provided in the blue main pixel B′ may be shorter than the period of the first main structures MNP1 (or the fourth main structures MNP4) forming the first main lens 151′ (or the fourth main lens 154′) provided in the green main pixel G′.

In the image sensor 1000 described above, the pixel array 1100′ may include a main pixel and a corner pixel that are different in size and the nano-photonic lens array 150′ may include a main lens corresponding to the main pixel and a corner lens each. The main lenses and the corner lenses described above may have a different sizes of effective lens profiles by including the plurality of nanostructures NP. By forming the main lens and the corner lens that are different in size by adjusting the shape, size (width and height), interval, and arrangement form of a plurality of nanostructures NP, the design degree of freedom and light efficiency of the image sensor may be improved.

The above-described image sensor 1000 may be an HDR image sensor and may be used for various high-performance optical apparatuses or high-performance electronic apparatuses. The electronic apparatus may be, for example, various portable devices such as a smart phone, a personal digital assistant (PDA), a laptop, a personal computer (PC), etc., a home appliance, a security camera, a medical camera, an automobile, an Internet of Things (IoT) apparatus, or other mobile or non-mobile computing devices, but is not limited thereto.

In addition to the image sensor 1000, the electronic apparatus may further include a processor, for example, an application processor (AP), to control the image sensor 1000, and may run an operating system or an application program through the processor to control a plurality of hardware or software components, and various data processing and operations may be performed. The processor may further include a graphic processing unit (GPU) and/or an image signal processor. If the processor contains an image signal processor, an image (or a moving image) obtained by the image sensor 1000 may be stored and/or output using the processor.

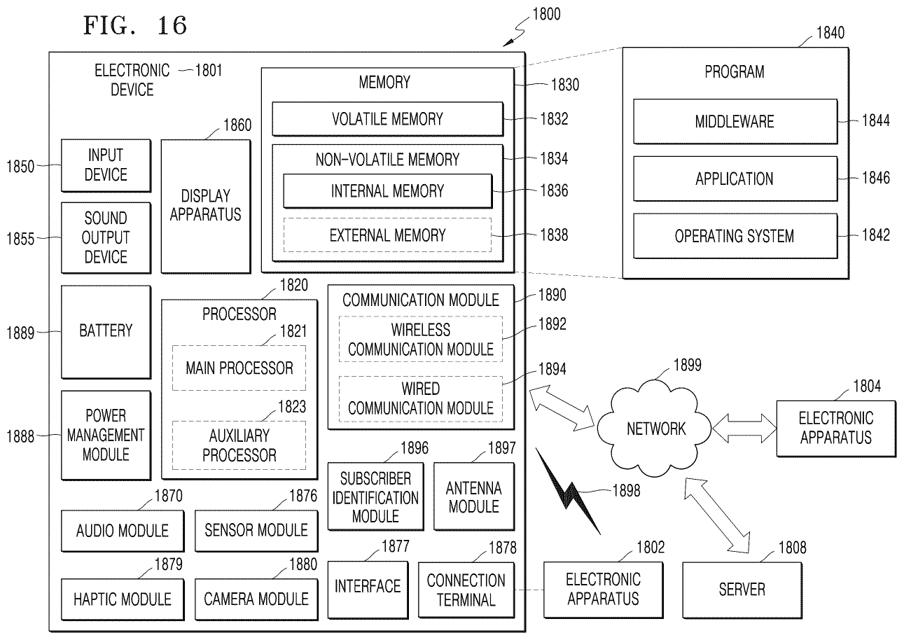

FIG. 16 is a block diagram illustrating an example of an electronic apparatus 1801 including the image sensor 1000. Referring to FIG. 16, in a network environment 1800, the electronic apparatus 1801 may communicate with another electronic apparatus 1802 through the first network 1898 (e.g., a short-range wireless communication network, etc.) or may communicate with another electronic apparatus 1804 and/or server 1808 through the second network 1899 (a long-range wireless communication network, etc.). The electronic apparatus 1801 may communicate with the electronic apparatus 1804 through the server 1808. The electronic apparatus 1801 may include a processor 1820, a memory 1830, an input apparatus 1850, a sound output apparatus 1855, a display apparatus 1860, an audio module 1870, a sensor module 1876, an interface 1877, a haptic module 1879, a camera module 1880, a power management module 1888, a battery 1889, a communication module 1890, a subscriber identification module 1896, and/or an antenna module 1897. In the electronic apparatus 1801, some (e.g., the display apparatus 1860, etc.) of the above elements may be omitted or other elements may be added. Some of the elements may be implemented as an integrated circuit. For example, the sensor module 1876 (e.g., a fingerprint sensor, an iris sensor, an illuminance sensor, etc.) may be embedded in the display apparatus 1860 (e.g., a display, etc.).

The processor 1820 may execute software (e.g., a program 1840) to control another element or a plurality of other elements (e.g., hardware, software components, etc.) of the electronic apparatus 1801 connected to the processor 1820 and may perform processing or operation of various data. As part of the data processing or operation, the processor 1820 may load commands and/or data received from other components (e.g., the sensor module 1876, the communication module 1890, etc.) onto the volatile memory 1832, process the commands and/or data stored in the volatile memory 1832, and store result data on the non-volatile memory 1834. The processor 1820 may include a main processor 8221 (e.g., a central processing apparatus, an application processor, etc.) and an auxiliary processor 1823 (e.g., a graphic processing apparatus, an image signal processor, a sensor hub processor, a communication processor, etc.) that may be operated independently from or together with the main processor 1821. The auxiliary processor 1823 may use less power than the main processor 1821 and perform specialized functions.

When the main processor 1821 is in an inactive state (a sleep state) or in an active state (an application execution state), the auxiliary processor 1823 may, either in place of or in conjunction with the main processor 1821, control functions and/or states of some components (e.g., the display apparatus 1860, the sensor module 1876, the communication module 1890, etc.) of the components of the electronic apparatus 1801. The auxiliary processor 1823 (e.g., an image signal processor, a communication processor, etc.) may be implemented as a portion of other components (e.g., the camera module 1880, the communication module 1890, etc.) that are technically related to the auxiliary processor 1823.

The memory 1830 may store various data required by the components (e.g., the processor 1820, the sensor module 1876, etc.) of the electronic apparatus 1801. Data may include, for example, software (e.g., the program 1840, etc.) and input data and/or output data of commands related to the software. The memory 1830 may include the volatile memory 1832 and/or the non-volatile memory 1834.

The program 1840 may be stored as a software in the memory 1830 and may include an operating system 1842, middleware 1844, and/or an application 1846.

The input apparatus 1850 may receive, from the outside (e.g., the user, etc.) of the electronic apparatus 1801, commands and/or data to be used in the components (e.g., the processor 1820) of the electronic apparatus 1801. The input apparatus 1850 may include a microphone, a mouse, a keyboard, and/or a digital pen (e.g., a stylus pen, etc.).

The sound output apparatus 1855 may output a sound signal to the outside of the electronic apparatus 1801. The sound output apparatus 1855 may include a speaker and/or a receiver. The speaker may be used for general purposes, such as playing multimedia or playing record, and the receiver may be used for receiving incoming calls. The receiver may be implemented as part of or separate from the speaker.

The display apparatus 1860 may visually provide information to the outside of the electronic apparatus 1801. The display apparatus 1860 may include a display, a hologram apparatus, or a projector and control circuitry to control a corresponding one of the display, the hologram apparatus, and the projector. The display apparatus 1860 may include touch circuitry adapted to detect a touch and/or sensor circuitry (e.g., a pressure sensor, etc.) adapted to measure the intensity of force incurred by the touch.

The audio module 1870 may convert sound to an electrical signal or convert the electrical signal to sound. The audio module 1870 may obtain the sound via the input apparatus 1850, or output the sound via the sound output apparatus 1855 and/or a speaker and/or headphone of another electronic apparatus (e.g., the electronic apparatus 1802) directly or wirelessly connected to the electronic apparatus 1801.

The sensor module 1876 may detect an operational state (e.g., power temperature, etc.) of the electronic apparatus 1801 or an external environmental state (e.g., a state of a user, etc.), and then generate an electrical signal and/or data value corresponding to the detected state. The sensor module 1876 may include a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 1877 may support one or more specified protocols to be used for the electronic apparatus 1801 to be connected with another electronic apparatus (e.g., the electronic apparatus 1802, etc.) directly or wirelessly. The interface 1877 may include a high definition multimedia interface (HDMI), a universal serial bus (USB) interface, a secure digital (SD) card interface, and/or an audio interface.

A connecting terminal 1878 may include a connector via which the electronic apparatus 1801 may be physically connected with another electronic apparatus (e.g., the electronic apparatus 1802, etc.). The connecting terminal 1878 may include a HDMI connector, a USB connector, a SD card connector, and/or an audio connector (e.g., a headphone connector, etc.).

The haptic module 1879 may convert an electrical signal into a mechanical stimulus (e.g., a vibration or a movement) or electrical stimulus which may be recognized by a user via his tactile sensation or kinesthetic sensation. The haptic module 1879 may include a motor, a piezoelectric element, and/or an electric stimulator.

The camera module 1880 may capture a still image or moving images. The camera module 1880 may include a lens assembly including one or more lenses, the image sensor 1000 of FIG. 1, image signal processors, and/or flashes. The lens assembly included in the camera module 1880 may collect light emitted from the subject, which is the target of image capturing.

The power management module 1888 may manage the power supplied to the electronic apparatus 1801. The power management module 1888 may be implemented as part of the power management integrated circuit (PMIC).

The battery 1889 may supply power to the components of the electronic apparatus 1801. The battery 1889 may include a primary cell which is not rechargeable, a secondary cell which is rechargeable, and/or a fuel cell.

The communication module 1890 may support establishing a direct (e.g., wired) communication channel and/or a wireless communication channel between the electronic apparatus 1801 and another electronic apparatus (e.g., the electronic apparatus 1802, the electronic apparatus 1804, the server 1808, etc.) and performing communication via the established communication channel. The communication module 1890 may include one or more communication processors that are operable independently from the processor 1820 (e.g., the application processor, etc.) and supports a direct t communication and/or a wireless communication. The communication module 1890 may include a wireless communication module 1892 (e.g., a cellular communication module, a short-range wireless communication module, a global navigation satellite system (GNSS) communication module, etc.) and/or a wired communication module 1894 (e.g., a local area network (LAN) communication module, a power line communication module, etc.). A corresponding one of these communication modules may communicate with another electronic device via a first network 1898 (e.g., a short-range communication network, such as Bluetooth™, wireless-fidelity (Wi-Fi) direct, or infrared data association (IrDA)) or a second network 1899 (e.g., a long-range communication network, such as a cellular network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 1892 may identify and authenticate the electronic apparatus 1801 in a communication network, such as the first network 1898 and/or the second network 1899, using subscriber information (e.g., international mobile subscriber identity (IMSI)) stored in the subscriber identification module 1896.

The antenna module 1897 may transmit or receive a signal and/or power to or from the outside (e.g., another electronic apparatus). The antenna may include a radiating element including a conductive pattern formed on a substrate (e.g., a printed circuit board (PCB)). The antenna module 1897 may include one or a plurality of antennas. If a plurality of antennas are included, an antenna appropriate for a communication scheme used in a communication network, such as the first network 1898 and/or the second network 1899, may be selected by the communication module 1890, from the plurality of antennas. Signals and/or power may be transmitted or received between the communication module 1890 and another electronic apparatus via the selected antenna. Another component (e.g., a radio frequency integrated circuit (RFIC), etc.) other than the antenna may be included as part of the antenna module 1897.

Some of the components are connected to each other through communication methods between peripheral devices (e.g., buses, general purpose input and output (GPIO), serial peripheral interface (SPI), and mobile industry processor interface (MIPI)) and may interchange signals (e.g., command and data) with each other.

The command or data may be transmitted or received between the electronic apparatus 1801 and the external electronic apparatus 1804 through the server 1808 connected to the second network 1899. The other electronic apparatuses 1802 and 1804 may be the same as or different from the electronic apparatus 1801. All or some of operations executed in the electronic apparatus 1801 may be executed in one or a plurality of the other electronic apparatuses 1802, 1804, and 1808. For example, when the electronic apparatus 1801 needs to perform a function or service, instead of executing a function or service itself, the electronic apparatus 1801 may request one or a plurality of other electronic apparatuses to perform part of or the entire function or service. One or a plurality of other electronic apparatuses that received the request may execute an additional function or service related to the request and may transmit a result of the execution to the electronic apparatus 1801. To this end, cloud computing, distributed computing, and/or client-server computing technology may be used.

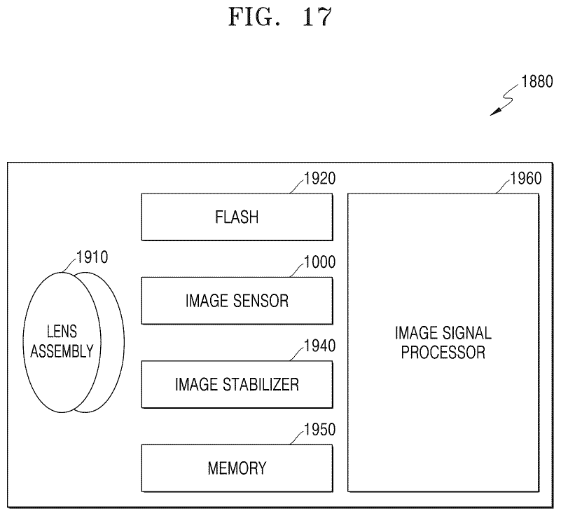

FIG. 17 is a block diagram illustrating the camera module 1880 of FIG. 16. Referring to FIG. 17, the camera module 1880 may include a lens assembly 1910, a flash 1920, the image sensor 1000 (see FIG. 1), an image stabilizer 1940, a memory 1950 (e.g., a buffer memory, etc.), and/or an image signal processor 1960. The lens assembly 1910 may collect light emitted from the subject, which is an object of an image capture. The camera module 1880 may include a plurality of lens assemblies 1910, and in this case, the camera module 1880 may be a dual camera, a 360-degree camera, or a spherical camera. Some of the plurality of lens assemblies 1910 may have the same lens properties (e.g., an angle of view, a focal length, an autofocus, an F number, an optical zoom, etc.), or different lens properties. The lens assembly 1910 may include a wide-angle lens or a telephoto lens.

The flash 1920 may emit light used to strengthen light emitted or reflected from the subject. The flash 1920 may include one or a plurality of light-emitting diodes (LED) (e.g., a red-green-blue (RGB) LED, a white LED, an infrared (IR) LED, an ultraviolet (UV) LED, etc.) and/or a xenon lamp. The image sensor 1000 may be the image sensor 1000 described in FIG. 1, and may obtain an image corresponding to the subject by converting light emitted or reflected from the subject and transmitted through the lens assembly 1910 into an electrical signal. The image sensor 1000 may include one or a plurality of sensors selected from image sensors having different properties, such as an RGB sensor, a black and white (BW) sensor, an IR sensor, or a UV sensor. Each sensor included in the image sensor 1000 may be implemented as, for example, a charge coupled device (CDD) sensor and/or a complementary metal oxide semiconductor (CMOS) image sensor.

The image stabilizer 1940 may, in response to a movement of the camera module 1880 or the electronic apparatus 1901 including the camera module 1880, move one or a plurality of lenses or image sensors 1000 included in the lens assembly 1910 in a certain direction or control (e.g., a control of read-out timing, etc.) operation characteristics of the image sensor 1000, so as to compensate for negative effects of the movement. The image stabilizer 1940 may detect the movement of the camera module 1880 or the electronic apparatus 1801 by using a gyro sensor (not shown) or an acceleration sensor (not shown) arranged inside or outside the camera module 188. The image stabilizer 1940 may be optically implemented.

The memory 1950 may store part of an image or the entire data obtained through the image sensor 1000 for a following image processing operation. For example, if a plurality of images are obtained at high speed, the obtained original data (e.g., Bayer-patterned data, high resolution data, etc.) may be stored in the memory 1950, only a low resolution image may be displayed, and original data of a selected (user selected, etc.) image may be transmitted to the image signal processor 1960. The memory 1950 may be integrated into the memory 1830 of the electronic apparatus 1801 or may be a separate memory that is independently operated.

The image signal processor 1960 may perform image processing for an image obtained through the image sensor 1000 or image data stored in the memory 1950. Image processing may include depth map generation, three-dimensional modeling, panorama generation, feature point extraction, image synthesis, and/or image compensation (e.g., noise reduction, resolution adjustment, brightness adjustment, blurring, softening, etc.). The image signal processor 1960 may perform controlling (e.g., exposure time control, lead out timing control, etc.) of components (e.g., image sensors 1000, etc.) included in the camera module 1880. The image treated by the image signal processor 1960 may be stored again in the memory 1950 for further processing or may be provided to an external component (e.g., the memory 1830, the display apparatus 1860, the electronic apparatus 1802, the electronic apparatus 1804, the server 1808, etc.). The image signal processor 1960 may be integrated into the processor 1820 or may be a separate processor operating independently of the processor 1820. If the image signal processor 1960 is a separate processor from the processor 1820, an image processed by the image signal processor 1960 may be displayed through the display apparatus 1860 after going through an additional image processing by the processor 1820.

The electronic apparatus 1801 may include a plurality of camera modules 1880 with different properties or functions. In this case, one of the plurality of camera modules 1880 may be a wide-angle camera and the other may be telephoto camera. Similarly, one of the plurality of camera modules 1880 may be a front-facing camera and the other may be a rear-facing camera.

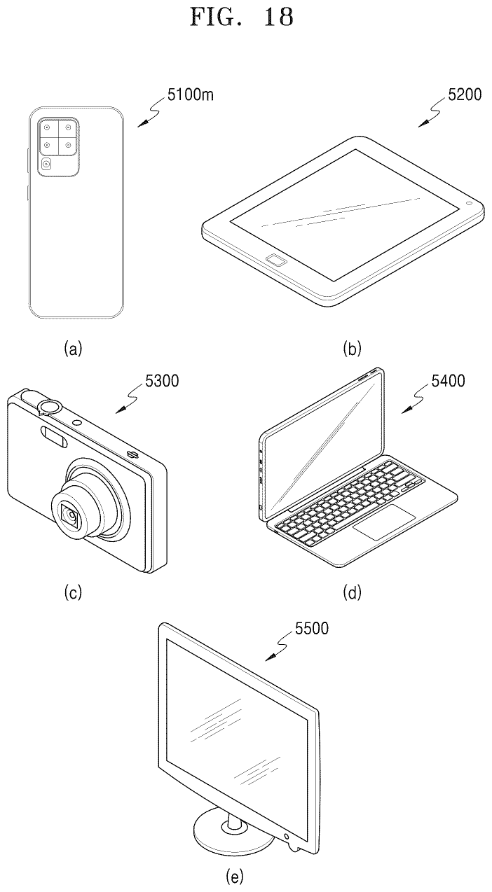

The image sensor 1000 according to some example embodiments may be applied to a mobile phone or a smartphone 5100m shown in FIG. 18 (a), a tablet or a smart tablet 5200 shown in FIG. 18 (b), a digital camera or a camcorder 5300 shown in FIG. 18 (c), a notebook computer 5400 shown in FIG. 18 (d), a television or a smart television 5500 shown in FIG. 18 (e), or the like. For example, the smartphone 5100m or the smart tablet 5200 may include a plurality of high-resolution cameras each including a high-resolution image sensor. The high-resolution cameras may be used to extract depth information of subjects in a moving image, control an out focusing of the moving image, or automatically identify the subjects in the moving image.

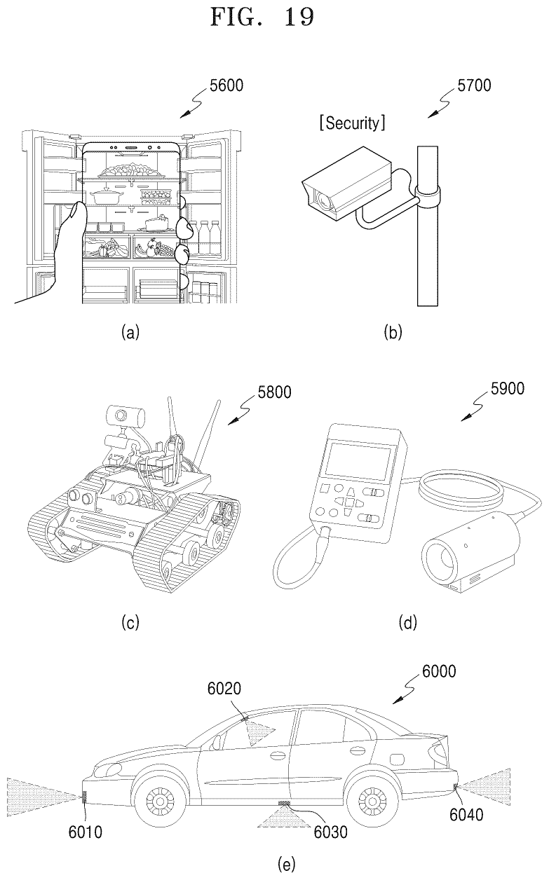

In addition, the image sensor 1000 may be applied to a smart refrigerator 5600 shown in FIG. 19 (a), a security camera 5700 shown in FIG. 19 (b), and a robot 5800 shown in FIG. 19 (c), and a medical camera 5900 shown in FIG. 19 (d). For example, the smart refrigerator 5600 may automatically recognize food in the refrigerator by using an image sensor and inform about the presence of a specific food, the types of food that are stocked or sold, etc. to the user through a smartphone. The security camera 5700 may provide an ultra-high resolution moving image and may allow objects or people in the moving image to be recognized even in a dark environment by using high sensitivity. The robot 5800 may be used in disasters or industrial sites that humans cannot directly access to provide high resolution images. The medical camera 5900 may provide high-resolution moving images for diagnosis or surgery and dynamically adjust the field of view.

In addition, the image sensor 1000 may be applied to a vehicle 6000 as shown in FIG. 19 (e). The vehicle 6000 may include a plurality of vehicle cameras 6010, 6020, 6030, and 6040 arranged in various positions. Each of the vehicle cameras 6010, 6020, 6030, and 6040 may include an image sensor according to an example embodiment. The vehicle 6000 may provide a variety of information about the inside or surrounding of the vehicle to the driver by using a plurality of vehicle cameras 6010, 6020, 6030, and 6040, and may automatically recognize objects or people in the moving image to provide information necessary for autonomous driving.

The image sensor including the nano-photonic microlens array and the electronic apparatus including the image sensor have been described above with reference to the example embodiments illustrated in the drawings but are only examples and it will be understood by those of ordinary skill in the art that various modifications and equivalent example embodiments may be made.

In the image sensor (e.g., the HDR image sensor) according to the example embodiment, the large main lens and the small corner lens may be configured by using the nanostructures to easily implement various sizes of main lenses and corner lenses.

According to the embodiments, the shape, size, interval, arrangement form, etc. of the plurality of nanostructures provided in the main lens and the corner lens may be controlled to implement the main lens and the corner lens having the desired size, curvature, effective lens profile, etc., and the design degree of freedom and light efficiency of the image sensor may be improved.

It should be understood that example embodiments described herein should be considered in a descriptive sense only and not for purposes of limitation. Descriptions of features or aspects within each example embodiment should typically be considered as available for other similar features or aspects in other embodiments. While example embodiments have been described with reference to the figures, it will be understood by those of ordinary skill in the art that various changes in form and details may be made therein without departing from the spirit and scope as defined by the following claims and their equivalents.

What is claimed is:

1. An image sensor comprising:
a sensor substrate comprising a plurality of sensing elements;
a color filter layer on the sensor substrate and comprising a plurality of color filters configured to transmit light of different colors; and
a nano-photonic lens array on the color filter layer and comprising a plurality of nanostructures that are configured to concentrate incident light on the plurality of sensing elements,
wherein the nano-photonic lens array comprises a plurality of main lenses and a plurality of corner lenses respectively corresponding to the plurality of main lenses, the plurality of corner lenses being smaller than the plurality of main lenses, and
wherein a size of each of the plurality of main lenses is three times or more larger than a size of each of the plurality of corner lenses.

2. The image sensor of claim 1, wherein each of the plurality of the main lenses and each of the plurality of the corner lenses corresponding to each other are adjacent to each other.

3. The image sensor of claim 1, wherein the plurality of main lenses comprise a first main lens and a second main lens, and
wherein the plurality of corner lenses comprise a first corner lens corresponding to the first main lens and a second corner lens corresponding to the second main lens.

4. The image sensor of claim 3, wherein the first main lens comprises a plurality of first main structures, the second main lens comprises a plurality of second main structures, the first corner lens comprises a plurality of first corner structures, and the second corner lens comprises a plurality of second corner structures.

5. The image sensor of claim 4, wherein an arrangement of sizes of the plurality of first main structures is different from an arrangement of sizes of the plurality of second main structures, and
wherein the plurality of first main structures and the plurality of second main structures are configured to form different phase profiles.

6. The image sensor of claim 4, wherein a period of the plurality of first main structures is different from a period of the plurality second main structures.

7. The image sensor of claim 4, wherein a period of the plurality of first main structures is different from a period of the plurality of first corner structures, and
wherein a period of the plurality of second main structures is different from a period of the plurality of second corner structures.

8. The image sensor of claim 4, wherein a period of the plurality of first main structures, a period of the plurality of second main structures, a period of the plurality of first corner structures, and a period of the plurality of second corner structures are identical to one another.

9. The image sensor of claim 8, wherein an arrangement of sizes of the plurality of first main structures is identical to an arrangement of sizes of the plurality of second main structures, and
wherein an arrangement of sizes of the plurality of first corner structures is identical to an arrangement of sizes of the plurality of second corner structures.

10. The image sensor of claim 4, wherein a size of each of the plurality of first main structures decreases and then increases toward a center of the first main lens from a periphery of the first main lens, and
wherein a size of each of the plurality of second main structures decreases and then increases toward a center of the second main lens from a periphery of the second main lens.

11. The image sensor of claim 4, wherein, based on incident light having a chief ray angle (CRA) greater than 0 being incident on the first main lens, the plurality of first main structures are asymmetrically arranged with respect to a center of the first main lens and the plurality of first corner structures are asymmetrically arranged with respect to a center of the first corner lens.

12. The image sensor of claim 1, wherein the plurality of pixels are periodically arranged in a first direction and a second direction perpendicular to the first direction, and
wherein the plurality of nanostructures are periodically arranged in the first direction and the second direction.

13. The image sensor of claim 1, wherein the plurality of pixels are arranged in a first direction and a second direction perpendicular to the first direction, and
wherein the plurality of nanostructures are periodically arranged in a direction between the first direction and the second direction.

14. The image sensor of claim 1, wherein the nano-photonic lens array comprises at least one layer comprising the plurality of nanostructures.

15. The image sensor of claim 1, further comprising an anti-reflection layer on the nano-photonic lens array.

16. The image sensor of claim 1, further comprising a planarization layer between the color filter layer and the nano-photonic lens array.

17. The image sensor of claim 16, further comprising an encapsulation layer between the planarization layer and the nano-photonic lens array.

18. The image sensor of claim 17, further comprising an etch stop layer between the encapsulation layer and the nano-photonic lens array.

19. An electronic apparatus comprising:
an image sensor configured to convert an optical image to an electrical signal; and
a processor configured to control an operation of the image sensor and store and output a signal generated from the image sensor,
wherein the image sensor comprises:
a sensor substrate comprising a plurality of pixels;
a color filter layer on the sensor substrate and comprising a plurality of color filters configured to transmit light of different colors; and
a nano-photonic lens array on the color filter layer and comprising a plurality of nanostructures that are configured to concentrate incident light on the plurality of pixels,
wherein the nano-photonic lens array comprises a plurality of main lenses and a plurality of corner lenses respectively corresponding to the plurality of main lenses, the plurality of corner lenses being smaller than the plurality of main lenses, and
wherein a size of each of the plurality of the main lenses is three times or more larger than a size of each of the plurality of the corner lenses.
